(19) United States
(12) Patent Application Publication
(10) Pub. No.: US 2024/0101822 A1
(43) Pub. Date: Mar. 28, 2024

(54) POLYAMIDE-IMIDE COPOLYMER FILM, PREPARATION METHOD THEREOF AND FLEXIBLE DISPLAY

(71) Applicant: ZHEJIANG OCAS NEW MATERIALS CO., LTD., Zhejiang (CN)

(72) Inventors: Qun ZHANG, Zhejiang (CN); Chuncai ZHU, Zhejiang (CN); Tao HU, Zhejiang (CN); Guolong LIU, Zhejiang (CN); Zhe XU, Zhejiang (CN)

(73) Assignee: ZHEJIANG OCAS NEW MATERIALS CO., LTD., Zhejiang (CN)

(21) Appl. No.: 18/036,653

(22) PCT Filed: Mar. 7, 2023
(86) PCT No.: PCT/CN2023/080130

§ 371 Date: Nov. 23, 2023

(30) Foreign Application Priority Data
May 17, 2022 (CN) 202210536326.0

(51) Int. Cl. C08L 79/08; B01J 31/02; C08J 5/18; H10K 77/10; H10K 85/10

(52) U.S. Cl. CPC C08L 79/085; B01J 31/0244; C08J 5/18; H10K 77/111; H10K 85/111; C08J 2379/08

(57) ABSTRACT

This application proposes a polyamide-imide copolymer film and a flexible display. The polyamide-imide copolymer film is obtained by copolymerizing aromatic dianhydride and aromatic dicarbonyl compound with aromatic diamine. Wherein, the aromatic dicarbonyl compounds include fluorinated aromatic dicarbonyl compound and non-fluorinated aromatic dicarbonyl compound. The polyamide-imide copolymer film can obtain a very low yellow degree index and dual refractive index, which is suitable for the substrate production of flexible display.

The present application claims priority to Chinese patent application NO. 202210536326.0, filed to the Chinese Patent Office on May 17, 2022, entitled “Polyamide-imide copolymer film, preparation method thereof and Flexible display”, the entire disclosure of which is incorporated herein by reference.

### BACKGROUND OF THE INVENTION

### Technical Field

The application relates to the field of optical material, and in particular, to a polyamide-imide copolymer film, preparation method thereof and flexible display.

### Background Art

Thin displays, such as liquid crystal display or organic light emitting diode display, are implemented in the form of touch screen panels. They are not only widely used for smart phone and tablet PC, but also for various smart devices characterized by portability such as various wearable devices.

The basic structure of flexible display can be divided into three main structures such as substrate, intermediate display media and thin film encapsulation. Among them, the flexible substrate as the support and protection component of the entire flexible display not only has an important impact on the display quality of the display, but also directly affects the service life of the device.

In summary, polyimide film has good thermal stability and lower linear thermal expansion coefficient (CTE), so it is considered to be the preferred substrate material for flexible display. However, the existing polyimide membrane is colored yellow or brown due to the tightness of the aromatic ring density, so the transmission rate in the visible light area is low, and the yellow color is displayed.

Therefore, in order to be able to be used for flexible displays, researchers are studying various methods to transform the yellow of polyimide into colorless transparency. However, on the one hand, the existing transparent polyimide generally has a larger double refraction, and the larger double refraction will delay the light, thereby reducing the black and white contrast of the display, increasing the color offset of different perspectives. On the other hand, the yellow index of the polyimide film is still relatively high, which is not enough to meet the performance required by flexible displays in the market.

### SUMMARY OF INVENTION

Based on the technical problems existing in the background, this application proposes a polyamide-imide copolymer film and its preparation method. The polyamide-imide copolymer film can obtain very low yellow degree index and dual refractive index, which is suitable for the substrate production of flexible display.

This application proposes a polyamide-imide copolymer film. The polyamide-imide copolymer film is obtained by copolymerizing aromatic dianhydride and aromatic dicarbonyl compounds with aromatic diamine.

Wherein, the aromatic dicarbonyl compounds include fluorinated aromatic dicarbonyl compound and non-fluorinated aromatic dicarbonyl compound.

In this application, the aromatic dicarbonyl compounds in the specific selection, include the fluorinated aromatic dicarbonyl compound and non-fluorinated aromatic dicarbonyl compound. In this way, the fluorine-substituted amide repeat units and the amide repeat units without fluoride replacement are in the molecular chain of the obtained polyamide-imide copolymer film at the same time. The existence of these two amide repeat units helps to destroy the regularity of molecules, increase the degree of freedom of the molecular chain and enhance flexibility. While achieving high light transparency and low yellow degree index, it can also achieve the synergy effect of reducing dual refractive index.

Wherein, the fluorinated aromatic dicarbonyl compound is tetrafluoro-terephthaloyl chloride.

Wherein, the non-fluorinated aromatic dicarbonyl compound is at least one of terephthaloyl chloride, isophthaloyl chloride or 4,4′-biphenyldicarboxylic dichloride.

Wherein, the molar ratio of the fluorinated aromatic dicarbonyl compound and the non-fluorinated aromatic dicarbonyl compound is 1-1.5:1.

In this application, the limitation of the molar ratio of the fluorinated aromatic dicarbonyl compound and the non-fluorinated aromatic dicarbonyl compound, can properly control the content of the repeat units of diimide and the repeat units of the amide in the molecular chain, thereby further improving the yellow degree index and dual refractive index of polyamide-imide copolymer film.

Wherein, the aromatic dianhydride is at least one of pyromellitic dianhydride, 3,3′, 4,4′-Biphenyltetracarboxylic dianhydride, 4,4′-hexafluoroisopropylidene)diphthalic anhydride, 3,3′,4,4′-benzophenonetetracarboxylic dianhydride, or 4,4′-oxydiphthalic dianhydride.

Wherein, the aromatic diamine is at least one of p-phenylenediamine, m-phenylenediamine, 4,4′-diaminobiphenyl, 2,2′-Bis(trifluoromethyl) diaminobiphenyl or 4,4′-oxydianiline.

Wherein, the molar ratio of the aromatic dianhydride and the aromatic dicarbonyl compound is 1: 1-4.

In this application, the limitation of the molar ratio of the aromatic dianhydride and the aromatic dicarbonyl compound, can further improve the yellow degree index and dual refractive index of polyamide-imide copolymer film, in ensuring that the inherent mechanical properties of polyamide-imide copolymer film are not deteriorated.

This application proposes a preparation method of polyamide-imide copolymer film, including:

After aggregating the aromatic dianhydride with the aromatic diamine, then aggregating with non-fluorinated aromatic dicarbonyl compound and fluorinated aromatic dicarbonyl compound in turn. After imidation, the obtained polyamide acid is cast into a film, which obtains the polyamide-imide copolymer film.

Wherein, the imidation is performed under the condition of catalyst and dehydration agent. the catalyst is at least one of pyridine, methylpyridine, quinoline, or isoquinoline. The dehydration agent is at least one of the acetic anhydride, propionic anhydride, or trifluoroacetic anhydride.

This application also proposes a flexible display, which includes the above polyamide-imide copolymer film.

The application proposes a polyamide-imide copolymer film and preparation method thereof. The fluorinated aromatic dicarbonyl compound and non-fluorinated aromatic dicarbonyl compound are taken as the starting raw material of the aromatic dicarbonyl compound to obtain polyamide-imide copolymer film. In this way, it can obtain extremely low dual refraction performance on the basis of maintaining colorless transparency, so it can be effectively applied to flexible display.

### DESCRIPTION OF EMBODIMENTS

This application proposes a polyamide-imide copolymer film, which is obtained by copolymerizing aromatic dianhydride and aromatic dicarbonyl compound with aromatic diamine. When the aromatic dicarbonyl compounds are mixtures of the fluorinated aromatic dicarbonyl compound and the non-fluorinated aromatic dicarbonyl compound, the obtained polyamide-imide copolymer film shows the effective improvement of the yellow degree index and dual refractive index. The dissolution of fluorinated aromatic dicarbonyl compound is relatively good than the non-fluorinated aromatic dicarbonyl compound, therefore, the two are compounded as the aromatic dicarbonyl compound, improving the yellow degree index and dual refractive index effectively, while ensuring the high transparency of the polyamide-amine membrane.

However, when only the aromatic dianhydride is fluoride aromatic dianhydride, and/or the aromatic diamine is fluoride aromatic diamine, the obtained polyamide-imide copolymer film does not show the improvement of the yellow degree index and dual refractive index. The aromatic dianhydride and/or the aromatic diamine, whether or not it is fluoride, has relatively good solubility. Therefore, when only the aromatic dianhydride is fluoride aromatic dianhydride, and/or the aromatic diamine is fluoride aromatic diamine, it cannot show the improvement of the yellow degree index and dual refractive index.

In this application, in order to obtain a polyamide-imide copolymer film with coordinate improvement of the yellow degree index and dual refractive index, the fluorinated aromatic dicarbonyl compound is preferably at least one of tetrafluoro-terephthaloyl chloride, monofluoro-terephthaloyl chloride, 2-fluoroisophthaloyl chloride or 4-fluoroisophthaloyl chloride, and the non-fluorinated aromatic dicarbonyl compound is preferably at least one of terephthaloyl chloride, isophthaloyl chloride or 4,4′-biphenyldicarboxylic dichloride.

In this application, in order to maintain the inherent mechanical properties of polyamide-imide copolymer film, the aromatic dianhydride is preferably at least one of pyromellitic dianhydride, 3,3′,4,4′-Biphenyltetracarboxylic dianhydride, 4,4′-hexafluoroisopropylidene)diphthalic anhydride, 3,3′,4,4′-benzophenonetetracarboxylic dianhydride, or 4,4′-oxydiphthalic dianhydride, and the aromatic diamine is preferably at least one of para-phenylenediamine, m-phenylenediamine, 4,4′-diaminobiphenyl, 2,2′-Bis(trifluoromethyl) diaminobiphenyl or 4,4′-oxydianiline.

The polyamide-imide copolymer film proposed in this application, is obtained by copolymerizing aromatic dianhydride and aromatic dicarbonyl compound with aromatic diamine, imidation and casting into a film. During the aggregation process, it is preferably to aggregate the aromatherapy two anhydride with the aromatic dihamine, and then add the non-fluorinated aromatic dicarbonyl compounds and the non-fluorinated aromatic dicarbonyl compounds. In this way, the required polyamide-imide copolymer is obtained with improvement of the yellow degree index and dual refractive index.

In this application, the above aggregation reaction reacts preferably 1 to 24 h in an inert atmosphere at 0 to 60° C. The solvent used in the reaction is N-methyl-2-pyrrolidone (NMP), dimethylformamide (DMF), dimethylacetamide (DMAc), or dimethyl sulfoxide (DMSO).

Below, the technical solutions of this application are explained in detail through specific embodiments. However, it should be clear that these embodiments are proposed for examples, it is not explained as the scope of limiting this application.

### Embodiment 1

A preparation method of polyamide-imide copolymer film, included:

Under the protection of nitrogen, 3.2023 g (10 mmol) of 2,2′-Bis(trifluoromethyl) diaminobiphenyl (TFDB) was added to 50 ml N,N-dimethylacetamide (DMAc) and stirred to dissolve completely. 1.3327 g (3 mmol) of 4,4′-hexafluoroisopropylidene)diphthalic anhydride (6FDA) was added thereto to stir and dissolve. And then 0.6091 g (3 mmol) of terephthaloyl chloride (TPC) was added thereto to stir and dissolve. 1.0999 g (4 mmol) of tetrafluoroterephthaloyl chloride was added thereto to continue to stir at room temperature for 6 h to obtain a polyamine solution. 1.58 g of pyridine and 2.04 g of acetate anhydride were added to the polyamide solution, stirring which at room temperature for 30 min, then stirring at 70° C. for 1 h. After the polyamide solution cooling to room temperature, the polymer was precipitated by using excessive methanol. The polymer was rinsed with a large amount of methanol after filtering, and the polyamide-imide copolymer resin is obtained after drying.

The polyamide-imide resin was added to N,N-dimethylacetamide (DMAc) to be completely dissolved, obtaining solution with a solid content of 10 wt %. The obtained solution was cast on the stainless steel plate. The solution was heated to 120° C. under the vacuum to dry for 1 h, continued to heated to 200° C. to dry for 1 h, then heated to 300° C. to dry for 0.5 h, dropped to room temperature and separated the film to get the polyamide-imide copolymer film. The thickness of the polyamide-imide copolymer film was controlled to 50 μm.

### Embodiment 2

A preparation method of polyamide-imide copolymer film, included:

Under the protection of nitrogen, 1.8423 g (10 mmol) of 4,4′-diaminobiphenyl (MSDS) was added to 50 ml N,N-dimethylacetamide (DMAc) and stirred to dissolve completely. 0.8827 g (3 mmol) of 3,3′,4,4′-Biphenyltetracarboxylic dianhydride (6FDA) was added thereto to stir and dissolve. And then 0.6091 g (3 mmol) of terephthaloyl chloride (TPC) was added thereto to stir and dissolve. 1.0999 g (4 mmol) of tetrafluoroterephthaloyl chloride was added thereto to continue to stir at room temperature for 6 h to obtain a polyamine solution. 1.58 g of pyridine and 2.04 g of acetate anhydride were added to the polyamide solution, stirring which at room temperature for 30 min, then stirring at 70° C. for 1 h. After the polyamide solution cooling to room temperature, the polymer was precipitated by using excessive methanol. The polymer was rinsed with a large amount of methanol after filtering, and the polyamide-imide copolymer resin is obtained after drying.

The polyamide-imide resin was added to N,N-dimethylacetamide (DMAc) to be completely dissolved, obtaining solution with a solid content of 10 wt %. The obtained solution was cast on the stainless steel plate. The solution was heated to 120° C. under the vacuum to dry for 1 h, continued to heated to 200° C. to dry for 1 h, then heated to 300° C. to dry for 0.5 h, dropped to room temperature and separated the film to get the polyamide-imide copolymer film. The thickness of the polyamide-imide copolymer film was controlled to 50 μm.

### Embodiment 3

A preparation method of polyamide-imide copolymer film, included:

Under the protection of nitrogen, 2.0024 g (10 mmol) of 4,4′-oxydianiline (ODA) was added to 50 ml N,N-dimethylacetamide (DMAc) to stir and dissolve completely. 0.9667 g (3 mmol) of 3,3′,4,4′-benzophenonetetracarboxylic dianhydride (BTDA) was added thereto to stir and dissolve. And then 0.6091 g (3 mmol) of terephthaloyl chloride (TPC) was added thereto to stir and dissolve. 1.0999 g (4 mmol) of tetrafluoroterephthaloyl chloride was added thereto to continue to stir at room temperature for 6 h to obtain a polyamine solution. 1.58 g of pyridine and 2.04 g of acetate anhydride were added to the polyamide solution, stirring which at room temperature for 30 min, then stirring at 70° C. for 1 h. After the polyamide solution cooling to room temperature, the polymer was precipitated by using excessive methanol. The polymer was rinsed with a large amount of methanol after filtering, and the polyamide-imide copolymer resin is obtained after drying.

The polyamide-imide resin was added to N,N-dimethylacetamide (DMAc) to be completely dissolved, obtaining solution with a solid content of 10 wt %. The obtained solution was cast on the stainless steel plate. The solution was heated to 120° C. under the vacuum to dry for 1 h, continued to heated to 200° C. to dry for 1 h, then heated to 300° C. to dry for 0.5 h, dropped to room temperature and separated the film to get the polyamide-imide copolymer film. The thickness of the polyamide-imide copolymer film was controlled to 50 μm.

### Embodiment 4

A preparation method of polyamide-imide copolymer film, included:

Under the protection of nitrogen, 3.2023 g (10 mmol) of 2,2′-Bis (trifluoromethyl) diaminobiphenyl (TFDB) was added to 50 ml N,N-dimethylacetamide (DMAc) to stir and dissolve completely. 1.3327 g (3 mmol) of 4,4′-hexafluoroisopropylidene)diphthalic anhydride (6FDA) was added thereto to stir and dissolve. And then 0.6091 g (3 mmol) of isophthaloyl chloride (IPC) was added thereto to stir and dissolve. 1.0999 g (4 mmol) of tetrafluoroterephthaloyl chloride was added thereto to continue to stir at room temperature for 6 h to obtain a polyamine solution. 1.58 g of pyridine and 2.04 g of acetate anhydride were added to the polyamide solution, stirring which at room temperature for 30 min, then stirring at 70° C. for 1 h. After the polyamide solution cooling to room temperature, the polymer was precipitated by using excessive methanol. The polymer was rinsed with a large amount of methanol after filtering, and the polyamide-imide copolymer resin is obtained after drying.

The polyamide-imide resin was added to N,N-dimethylacetamide (DMAc) to be completely dissolved, obtaining solution with a solid content of 10 wt %. The obtained solution was cast on the stainless steel plate. The solution was heated to 120° C. under the vacuum to dry for 1 h, continued to heated to 200° C. to dry for 1 h, then heated to 300° C. to dry for 0.5 h, dropped to room temperature and separated the film to get the polyamide-imide copolymer film. The thickness of the polyamide-imide copolymer film was controlled to 50 μm.

### Embodiment 5

A preparation method of polyamide-imide copolymer film, included:

Under the protection of nitrogen, 3.2023 g (10 mmol) of 2,2′-Bis(trifluoromethyl) diaminobiphenyl (TFDB) was added to 50 ml N,N-dimethylacetamide (DMAc) to stir and dissolve completely. 2.2211 g (5 mmol) of 4,4′-hexafluoroisopropylidene)diphthalic anhydride (6FDA) was added thereto to stir and dissolve. And then 0.4060 g (2 mmol) of terephthaloyl chloride (TPC) was added thereto to stir and dissolve. 0.8249 g (3 mmol) of tetrafluoroterephthaloyl chloride was added thereto to continue to stir at room temperature for 6 h to obtain a polyamine solution. 1.58 g of pyridine and 2.04 g of acetate anhydride were added to the polyamide solution, stirring which at room temperature for 30 min, then stirring at 70° C. for 1 h. After the polyamide solution cooling to room temperature, the polymer was precipitated by using excessive methanol. The polymer was rinsed with a large amount of methanol after filtering, and the polyamide-imide copolymer resin is obtained after drying.

The polyamide-imide resin was added to N,N-dimethylacetamide (DMAc) to be completely dissolved, obtaining solution with a solid content of 10 wt %. The obtained solution was cast on the stainless steel plate. The solution was heated to 120° C. under the vacuum to dry for 1 h, continued to heated to 200° C. to dry for 1 h, then heated to 300° C. to dry for 0.5 h, dropped to room temperature and separated the film to get the polyamide-imide copolymer film. The thickness of the polyamide-imide copolymer film was controlled to 50 μm.

### Embodiment 6

A preparation method of polyamide-imide copolymer film, included:

Under the protection of nitrogen, 3.2023 g (10 mmol) of 2,2′-Bis(trifluoromethyl) diaminobiphenyl (TFDB) was added to 50 ml N,N-dimethylacetamide (DMAc) to stir and dissolve completely. 0.8885 g (2 mmol) of 4,4′-hexafluoroisopropylidene)diphthalic anhydride (6FDA) was added thereto to stir and dissolve. And then 0.8121 g (4 mmol) of terephthaloyl chloride (TPC) was added thereto to stir and dissolve. 1.0999 g (4 mmol) of tetrafluoroterephthaloyl chloride was added thereto to continue to stir at room temperature for 6 h to obtain a polyamine solution. 1.58 g of pyridine and 2.04 g of acetate anhydride were added to the polyamide solution, stirring which at room temperature for 30 min, then stirring at 70° C. for 1 h. After the polyamide solution cooling to room temperature, the polymer was precipitated by using excessive methanol. The polymer was rinsed with a large amount of methanol after filtering, and the polyamide-imide copolymer resin is obtained after drying.

The polyamide-imide resin was added to N,N-dimethylacetamide (DMAc) to be completely dissolved, obtaining solution with a solid content of 10 wt %. The obtained solution was cast on the stainless steel plate. The solution was heated to 120° C. under the vacuum to dry for 1 h, continued to heated to 200° C. to dry for 1 h, then heated to 300° C. to dry for 0.5 h, dropped to room temperature and separated the film to get the polyamide-imide copolymer film. The thickness of the polyamide-imide copolymer film was controlled to 50 μm.

Comparison 1

A preparation method of polyamide-imide copolymer film, included:

Under the protection of nitrogen, 3.2023 g (10 mmol) of 2,2′-Bis (trifluoromethyl) diaminobiphenyl (TFDB) was added to 50 ml N,N-dimethylacetamide (DMAc) to stir and dissolve completely. 1.3327 g (3 mmol) of 4,4′-hexafluoroisopropylidene)diphthalic anhydride (6FDA) was added thereto to stir and dissolve. And then 0.6091 g (3 mmol) of terephthaloyl chloride (TPC) was added thereto to stir and dissolve. 0.8121 g (4 mmol) of isophthaloyl chloride (IPC) was added thereto to continue to stir at room temperature for 6 h to obtain a polyamine solution. 1.58 g of pyridine and 2.04 g of acetate anhydride were added to the polyamide solution, stirring which at room temperature for 30 min, then stirring at 70° C. for 1 h. After the polyamide solution cooling to room temperature, the polymer was precipitated by using excessive methanol. The polymer was rinsed with a large amount of methanol after filtering, and the polyamide-imide copolymer resin is obtained after drying.

The polyamide-imide resin was added to N,N-dimethylacetamide (DMAc) to be completely dissolved, obtaining solution with a solid content of 10 wt %. The obtained solution was cast on the stainless steel plate. The solution was heated to 120° C. under the vacuum to dry for 1 h, continued to heated to 200° C. to dry for 1 h, then heated to 300° C. to dry for 0.5 h, dropped to room temperature and separated the film to get the polyamide-imide copolymer film. The thickness of the polyamide-imide copolymer film was controlled to 50 μm.

Comparison 2

A preparation method of polyamide-imide copolymer film, included:

Under the protection of nitrogen, 3.2023 g (10 mmol) of 2,2′-Bis(trifluoromethyl) diaminobiphenyl (TFDB) was added to 50 ml N,N-dimethylacetamide (DMAc) to stir and dissolve completely. 1.3327 g (3 mmol) of 4,4′-hexafluoroisopropylidene)diphthalic anhydride (6FDA) was added thereto to stir and dissolve. And then 0.8121 g (4 mmol) of terephthaloyl chloride (TPC) was added thereto to stir and dissolve. 0.8249 g (3 mmol) of tetrafluoroterephthaloyl chloride was added thereto to continue to stir at room temperature for 6 h to obtain a polyamine solution. 1.58 g of pyridine and 2.04 g of acetate anhydride were added to the polyamide solution, stirring which at room temperature for 30 min, then stirring at 70° C. for 1 h. After the polyamide solution cooling to room temperature, the polymer was precipitated by using excessive methanol. The polymer was rinsed with a large amount of methanol after filtering, and the polyamide-imide copolymer resin is obtained after drying.

The polyamide-imide resin was added to N,N-dimethylacetamide (DMAc) to be completely dissolved, obtaining solution with a solid content of 10 wt %. The obtained solution was cast on the stainless steel plate. The solution was heated to 120° C. under the vacuum to dry for 1 h, continued to heated to 200° C. to dry for 1 h, then heated to 300° C. to dry for 0.5 h, dropped to room temperature and separated the film to get the polyamide-imide copolymer film. The thickness of the polyamide-imide copolymer film was controlled to 50 μm.

Comparison 3

A preparation method of polyamide-imide copolymer film, included:

Under the protection of nitrogen, 3.2023 g (10 mmol) of 2,2′-Bis (trifluoromethyl) diaminobiphenyl (TFDB) was added to 50 ml N,N-dimethylacetamide (DMAc) to stir and dissolve completely. 1.3327 g (3 mmol) of 4,4′-hexafluoroisopropylidene)diphthalic anhydride (6FDA) was added thereto to stir and dissolve. And then 0.3451 g (1.7 mmol) of terephthaloyl chloride (TPC) was added thereto to stir and dissolve. 0.6324 g (2.3 mmol) of tetrafluoroterephthaloyl chloride was added thereto to continue to stir at room temperature for 6 h to obtain a polyamine solution. 1.58 g of pyridine and 2.04 g of acetate anhydride were added to the polyamide solution, stirring which at room temperature for 30 min, then stirring at 70° C. for 1 h. After the polyamide solution cooling to room temperature, the polymer was precipitated by using excessive methanol. The polymer was rinsed with a large amount of methanol after filtering, and the polyamide-imide copolymer resin is obtained after drying.

The polyamide-imide resin was added to N,N-dimethylacetamide (DMAc) to be completely dissolved, obtaining solution with a solid content of 10 wt %. The obtained solution was cast on the stainless steel plate. The solution was heated to 120° C. under the vacuum to dry for 1 h, continued to heated to 200° C. to dry for 1 h, then heated to 300° C. to dry for 0.5 h, dropped to room temperature and separated the film to get the polyamide-imide copolymer film. The thickness of the polyamide-imide copolymer film was controlled to 50 μm.

Performance Test:
light transmittance (T550): The light transmittance was measured at 550 nm by using an ultraviolet spectrophotometry (X-Rite CI7800).

Yellow degree index (YI): According to the ASTM E313 standard, the yellow degree index was measured at 550 nm using an ultraviolet spectrophotometry (X-Rite CI7800).

Dual refractive index: Using a prism coupling (Metricon 2010/m), the refractive indexs were measured in the TE (horizontal radio wave) mode and the TM (horizontal magnetic wave) mode at the 594 nm measurement wavelength, and the difference between which was the dual refractive index.

Elastic modulus: According to the ASTMD882 standard, the elastic modulus was measured with a thin film tensile test machine at a room temperature of 25° C.

The performance test results of the polyamide-imide copolymer films in the above embodiments and comparisons are shown in Table 1 as follows.

TABLE 1
The performance test results of the polyamide-imide
copolymer films in the embodiments and comparisons

| | light | Dual | Yellow | Elastic |
|---|---|---|---|---|
| | transmittance | refractive | degree index | modulus |
| | (%) | index | (YI) | (GPa) |
| Embodiment 1 | 90.2 | 0.016 | 1.86 | 5.72 |
| Embodiment 2 | 89.0 | 0.032 | 2.22 | 5.60 |
| Embodiment 3 | 89.2 | 0.029 | 2.16 | 5.83 |
| Embodiment 4 | 88.9 | 0.033 | 2.25 | 5.78 |
| Embodiment 5 | 89.6 | 0.021 | 2.05 | 5.61 |
| Embodiment 6 | 89.1 | 0.028 | 2.19 | 5.93 |
| Comparison 1 | 88.7 | 0.071 | 3.08 | 5.74 |
| Comparison 2 | 88.2 | 0.063 | 2.95 | 5.55 |
| Comparison 3 | 87.8 | 0.098 | 3.29 | 6.03 |

It can be seen from the above Table 1 that, the polyamide-imide copolymer films described in the embodiment of this application shows a high light transmission rate, and has a low yellow degree index and low dual refractive index.

The above is only the preferred embodiment of the present application, but the scope of protection of the present application is not limited thereto, and any equivalents or modifications of the technical solutions of the present application and the application concept thereof should be comprised in the scope of the present application within the scope of the technical scope of the present application.

What is claimed is:

1. A polyamide-imide copolymer film, which is obtained by copolymerizing an aromatic dianhydride and aromatic dicarbonyl compounds with an aromatic diamine,
wherein the aromatic dicarbonyl compounds include a fluorinated aromatic dicarbonyl compound and a non-fluorinated aromatic dicarbonyl compound.

2. The polyamide-imide copolymer film according to claim 1, wherein the fluorinated aromatic dicarbonyl compound is tetrafluoroterephthaloyl chloride.

3. The polyamide-imide copolymer film according to claim 1, wherein the non-fluorinated aromatic dicarbonyl compound is at least one of terephthaloyl chloride, isophthaloyl chloride or 4,4′-biphenyldicarboxylic dichloride.

4. The polyamide-imide copolymer film according to claim 1, wherein a molar ratio of the fluorinated aromatic dicarbonyl compound and the non-fluorinated aromatic dicarbonyl compound is 1-1.5:1.

5. The polyamide-imide copolymer film according to claim 1, wherein the aromatic dianhydride is at least one of pyromellitic dianhydride, 3,3′,4,4′-biphenyltetracarboxylic dianhydride, 4,4′-hexafluoroisopropylidene)diphthalic anhydride, 3,3′,4,4′-benzophenonetetracarboxylic dianhydride, or 4,4′-oxydiphthalic dianhydride.

6. The polyamide-imide copolymer film according to claim 1, wherein, the aromatic diamine is at least one of para-phenylenediamine, m-phenylenediamine, 4,4′-diaminobiphenyl, 2,2′-bis(trifluoromethyl) diaminobiphenyl or 4,4′-oxydianiline.

7. The polyamide-imide copolymer film according to claim 1, wherein a molar ratio of the aromatic dianhydride and the aromatic dicarbonyl compounds is 1: 1-4.

8. A preparation method of a polyamide-imide copolymer film, comprising:
after aggregating an aromatic dianhydride with an aromatic diamine, then aggregating with a non-fluorinated aromatic dicarbonyl compound and a fluorinated aromatic dicarbonyl compound in turn, casting the obtained polyamide acid into a film after imidation, which obtains the polyamide-imide copolymer film.

9. The preparation method of the polyamide-imide copolymer film according to claim 8, wherein the imidation is performed under a condition of a catalyst and a dehydration agent, the catalyst is at least one of pyridine, methylpyridine, quinoline, or isoquinoline, and the dehydration agent is at least one of acetic anhydride, propionic anhydride, or trifluoroacetic anhydride.

10. A flexible display, which comprises the polyamide-imide copolymer film according to claim 1.
